(19) United States
(12) Patent Application Publication
(10) Pub. No.: US 2003/0006839 A1
(43) Pub. Date: Jan. 9, 2003

(54) Extended range power detector and amplifier and method

(76) Inventor: Paul P. Chominski, San Diego, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/896,001

(22) Filed: Jun. 28, 2001

(51) Int. Cl. H03G 3/20

(52) U.S. Cl. 330/140

(57) ABSTRACT

In an extended range amplifier, a simplified feedback system is provided to control a voltage control attenuator (or voltage control variable gain amplifier). The feedback loop may be embodied in analog or digital form. An input signal is applied to a variable gain or variable attenuating amplifier and, preferably, to a linear diode detector. The system logarithmic output is taken from the variable controlled device, and the linear diode detector supplies a linear output. The linear output from the diode detector is compared with a reference level. A resulting error signal is used to control the attenuation of the voltage control attenuator. In this matter, the simplified, reliable adjustment of extended dynamic range of amplification and power measurement are provided. The selection of reference level of the attenuator or amplifier will determine the gain of the amplifier.

### FIELD OF INVENTION

The present invention relates to power control in communications systems.

### BACKGROUND OF THE INVENTION

A significant application of power detectors and amplifiers is in solid state communications circuits. However, the teachings herein are not limited to solid state communications circuits. It is highly desirable to have a circuit that can handle amplification for attenuation of a wide range of input signals. Many input automatic gain control amplifiers, or variable attenuators provide logarithmic signal outputs. This has the advantage of spreading input signals at a lower end of the range and compressing input signals at the higher end of a range, thus contributing to dynamic range of the input amplifying stage.

Prior art circuits also have as an objective providing logarithmic outputs and linear outputs. Prior arrangements have been complicated. They may include a plurality of stages. Such complex circuits or multi-stage circuits have difficulty in achieving necessary operations within real time with respect to the input signals. In the past, wireless communications devices, for example, cell phones, have been primarily concerned with voice data which is input to a system at a relatively low rate. However, a larger percentage of wireless phone communications is shifting to data transmission. Data transmission occurs at much higher rates than voice transmission. Therefore, it is important to provide a simplified architecture for controlling power output from an amplifier receiving input signals. It is also important to provide few stages as possible for better response to high speed inputs. Additionally, it is desirable to have the ability for power measurement.

Significant applications include, for example, power ramping and receivers conforming to the mobile Global System For Mobile Communications Standards (GSM), the de facto standard in Europe and Asia. Other applications include open loop power control Code-Division Multiple Access (CDMA), Wide-Band CDMA (CDMA) and Received Signal Strength Indicator (RSSI) receivers.

### SUMMARY OF THE INVENTION

Briefly stated in accordance with the present invention, in an extended range amplifier, a simplified feedback system is provided to control a voltage control attenuator (or voltage control variable gain amplifier). The feedback loop may be embodied in analog or digital form. An input signal is applied to a variable gain or variable attenuating amplifier and, preferably, to a linear diode detector. The system logarithmic output is taken from the variable controlled device, and the linear diode detector supplies a linear output. The linear output from the diode detector is compared with a reference level. A resulting error signal is used to control the attenuation of the voltage control attenuator. In this matter, the simplified, reliable adjustment of extended dynamic range of amplification and power measurement are provided. The selection of reference level of the attenuator or amplifier will determine the gain of the amplifier.

### BRIEF DESCRIPTION OF THE DRAWINGS

The means and method through which the foregoing invention is achieved are pointed out with particularity in the claims forming the concluding portion of the specification. The invention, both as to its organization and manner of operation may be further understood by reference to the following description taken in connection with the following drawings.

Of the drawings:

FIG. 1 is a block diagrammatic representation of an extended dynamic range power detector and amplifier;

FIG. 2 is a block diagrammatic representation of another embodiment of the system of FIG. 1 utilizing a voltage control gain amplifier;

FIG. 3 is a further embodiment of the present invention utilizing a digital feedback loop; and

FIG. 4 is a chart representing the method of the present invention.

### DETAILED DESCRIPTION OF THE INVENTION

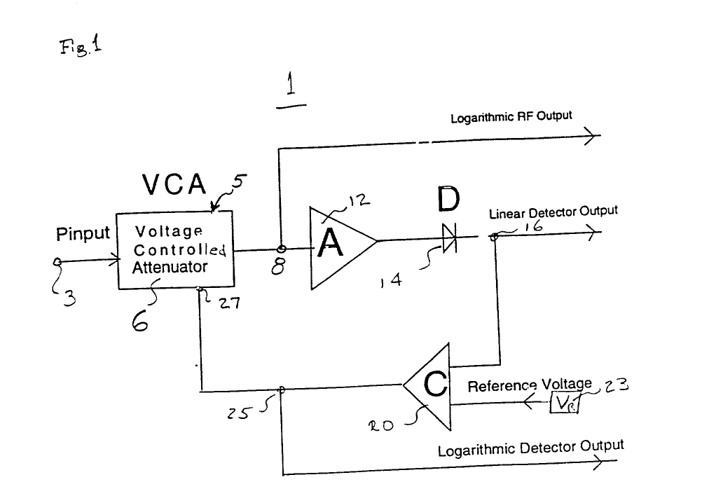

FIG. 1 is a block diagrammatic representation of an extended dynamic range power detector and amplifier 1 constructed in accordance with the present invention. A radio frequency input is applied to an input terminal 3. The amplifier 1 is used to respond to radio frequencies in telecommunications applications such as cell phones. In other embodiments, the input to the input terminal 3 may have a frequency outside the range of radio frequency. The input signal is coupled to a controlled variable amplifier 5. This term is used herein to describe either a variable attenuator or a variable gain amplifier since either an attenuator or a amplifier multiplies the input signal 3, whether by a factor greater or less than 1. In the embodiment of FIG. 1, a controlled variable amplifier comprises a voltage controlled attenuator 6. The variable controlled amplifier 5 has an output terminal 8. The output at terminal 8 is logarithmically related to the signal at the input terminal 3.

The output terminal 8 provides an input to an amplifier 12 which in turn provides an input to a linear diode detector 14 having an output at a terminal 16. The output terminal 16 provides a linear output indicative of power measurement. The amplifier 12 is not an essential component but, is included in many forms. Uses of the amplifier 12 could include matching the output at terminal 16 to the range of a comparator 20. The comparator 20 has one input connected to the output terminal 16 and a second input connected to a reference voltage V_{R}23. The output of the comparator 20 is connected to a logarithmic detector output terminal 25. This output is also connected to a control terminal 27 of the voltage controlled attenuator 6.

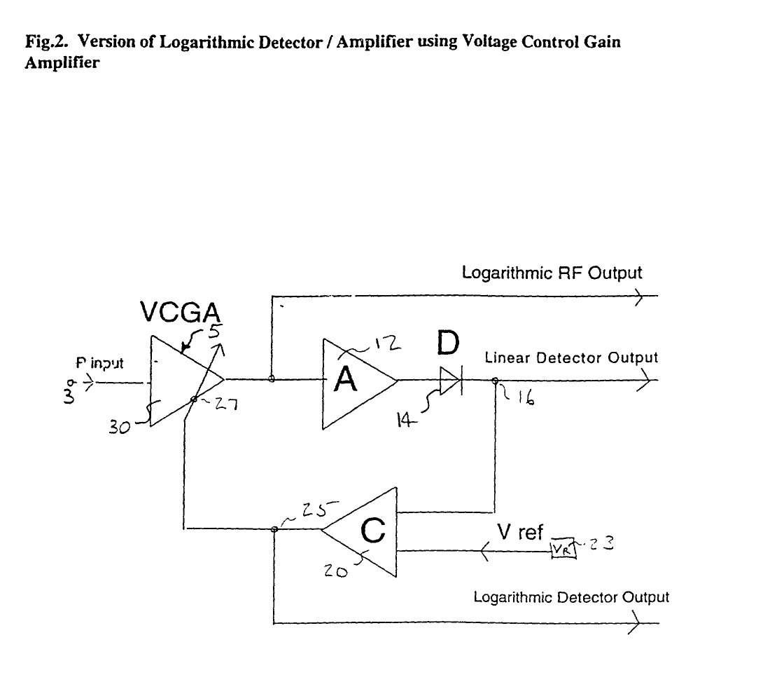

In the embodiment of FIG. 2, which is also a block diagrammatic representation of an extended range power detector and amplifier constructed in accordance with the present invention, the controlled amplifier 5 comprises a voltage controlled gain amplifier 30. The voltage controlled gain amplifier 30 is particularly suited in applications where a range of input signals having a lower amplitude than signals applied to the input terminal 3 in the embodiment of FIG. 1 are expected.

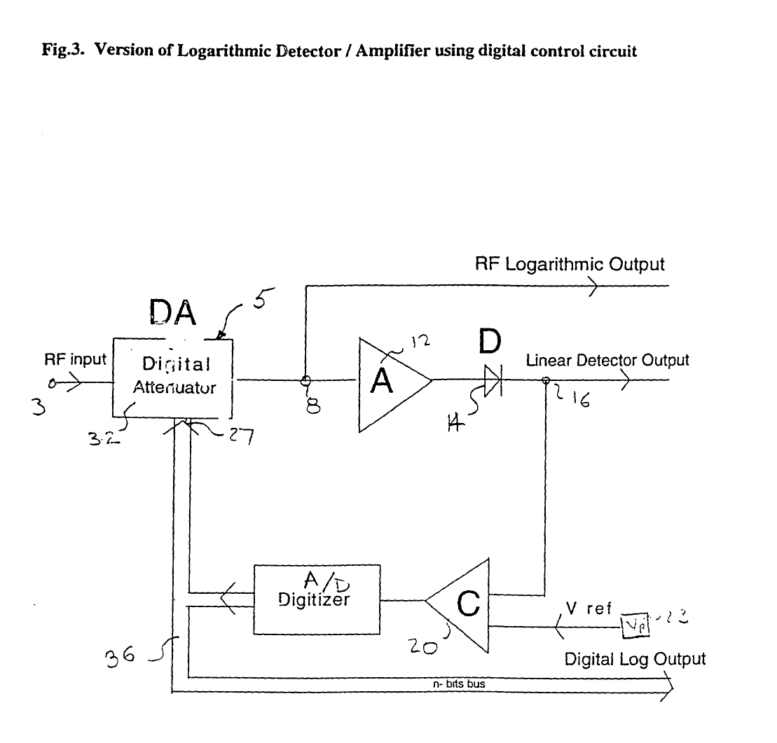

In the embodiment of FIG. 3, feedback and control are performed in the digital domain. The controlled variable amplifier 5 comprises a digital attenuator 32. The output of the comparator 20 is provided to an analog to digital converter 44 which provides a digital output to an n-bit bus 36. The bus provides a digital number for controlling the digital attenuator 32 and provides a digital log output indicative of the output of the comparator 20. In the digital embodiment, greater resolution of the error signal provided from the comparator 20 is provided.

In selected embodiments, the fixed gain amplifier 12 is selected to have a proper level match to characteristics of the linear diode detector 14. However, in other embodiments the fixed gain amplifier 12 may be omitted. If the signal level is high enough to drive the diode detector 13. For example, the circuit could be connected to sample the output to the antenna in a hand-held or base station. Similarly, the diode detector 14 is matched with the comparator 20 to provide outputs in a range of operating voltage levels of the comparator 20. When the voltage at the terminal 16 is less than V_{R}, the comparator 20 provides a voltage to control the variable amplifier 5 to decrease attenuation. If the voltage at terminal 16 is higher than V_{R}, then the comparator 20 provides an output to generate a voltage to increase the attenuation of the controlled amplifier 5. The system 1 hunts until the voltage at terminal 16 equals V_{R}. The variable controlled amplifier 5 is preferably selected so that its attenuation in dB is essentially a linear function of the control voltage, or digital number, via the terminal or interface 27. Then the voltage at terminal 8 will have essentially the same logarithmic characteristic. Consequently, logarithmic radio frequency outputs will have a logarithmic amplitude relation to the radio frequency input at terminal 3. The operating point of the variable controlled amplifier 5 is set by selecting the level of V_{R}.

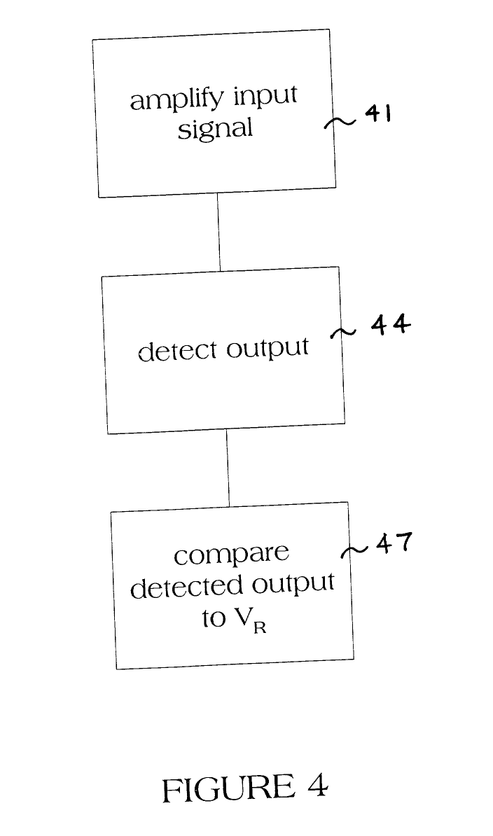

The method of the present invention is described with respect to FIG. 4, which is a flow chart. At block 41, the input signal at the terminal 3 is amplified by the controlled amplifier 5. The output of the controlled amplifier 5 or amplifier 12, depending on the construction of the embodiment is detected by the linear detector 14 as indicated at block 44. At block 47 the detected output is compared to V_{R}. The error signal from the comparator 20 is applied to controlled variation of the variable amplifier 5. Discussed above, the level at which a zero error signal is provided from the comparator 20 is determined by the selection of V_{R}.

The present circuit also functions as a power measurement circuit. Power measurement may be accomplished as indicated at block 52 by reading the power level at terminal 16. Note that in the circuit of FIG. 3, the digital attenuator may be set to provide discreet steps such as 0.5, 1 or 2 dB per step or least significant bit (LSB). Digitizer may take other forms as well as a digital to analog converter.

### EXAMPLES

Assuming following parameters of the circuit components:

VCA insertion loss (minimum attenuation) IL_min=3 db

VCA control characteristic: −20 dB/V

VCA range: 60 dB

Gain of the Amplifier A: G-63 dB

Detector: for P_in_det=0 dBm V_det_out=1 V at 1000 ohm

The following table shown signals levels across the circuit for input signal in range from −70 dBm to +10 dBm:

| | Power at | | Linear | |
|---|---|---|---|---|
| | VCA output | Power at | Detector | |
| P_in[dBm] | [dBm] | Detector input | Output[V] | Low Output |
| −70 | −73 | −10 | 0.32 | 0 |
| −60 | −63 | 0 | 1 | 0 |
| −50 | −63 | 0 | 1 | 0.5 |
| −40 | −63 | 0 | 1 | 1 |
| −30 | −63 | 0 | 1 | 1.5 |
| −20 | −63 | 0 | 1 | 2 |
| −10 | −63 | 0 | 1 | 2.5 |
| 0 | −63 | 0 | 1 | 3 |
| 10 | −53 | 10 | 3.16 | 3 |

What is thus provided is an efficient, simple extended dynamic range power amplifier and an extended dynamic range power detector. It will be understood that by those skilled in the art various changes in form and detail may be made in the particular circuits illustrated and method described without the departing from the spirit and scope of the invention.

What is claimed is:

1. An extended dynamic range amplifier comprising:
a variable controlled amplifier for receiving an input at an operating frequency, said controlled amplifier providing a substantially logarithmic function to said input signal and providing an output;
a linear detector receiving a signal based on said output and providing a response indicative thereof; and
a comparator to compare said linear detector output to a reference level voltage, said comparator providing an error output connected to a control terminal of said variable amplifier.

2. The system of claim 1 further comprising a linear amplifier connected between said controlled amplifier and said linear detector.

3. The system of claim 2 further comprising a reference voltage source connected to an input of said comparator for comparison to said linear detector output.

4. The system according to claim 3 wherein said controlled amplifier comprises a voltage controlled attenuator.

5. The system of claim 3 wherein said variable amplifier comprises a voltage controlled gain amplifier.

6. The system according to claim 3 wherein said variable amplifier comprises a digital attenuator.

7. The system according to claim 6 further comprising a digitizer connected to the output of said comparator and a digital bus connecting the coupling the output of said digitizer to said digital attenuator.

8. The system of claim 7 wherein said digitizer comprises an analog to digital converter.

9. The system according to claim 3 wherein an output indicative of power level at said input of said controlled amplifier is provided at the output of said controlled amplifier.

10. A method for controlling gain of a controlled amplifier comprising the steps of:
amplifying an input signal to said amplifier;
detecting a signal incorporating said amplifier output;
comparing the detective signal to a reference voltage, generating an error signal based on the difference between said reference voltage and said detected output; and
coupling said error signal to control said controlled amplifier.

11. The claim according to claim 10 wherein the step of controlling said controlled amplifier comprises controlling the attenuation provided by said amplifier.

12. The claim according to claim 10 wherein the step of controlling said controlled amplifier comprises controlling the gain thereof.
